(19) United States
(12) Patent Application Publication
(10) Pub. No.: US 2005/0184388 A1
(43) Pub. Date: Aug. 25, 2005

(54) Seal ring design without stop layer punch through during via etch

(75) Inventors: Hsin-Ching Shih, Hsin-Chu County (TW); Kang-Cheng Lin, Yonghe City (TW); Chao-Cheng Chen, Chong-Ling (TW); Hun-Jan Tao, Hsinchu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co.

(21) Appl. No.: 10/782,365

(22) Filed: Feb. 19, 2004

(51) Int. Cl. H01L 23/48

(52) U.S. Cl. 257/734

(57) ABSTRACT

In accordance with the objective of the invention a new method is provided for the creation of a seal ring having dissimilar elements. The Critical Dimensions of the seal ring are selected with respect to the CD of other device features, such a seal vias, such that the difference in etch sensitivity between the created seal ring and the via holes is removed. All etch of the simultaneously etched features is completed at the same time, avoiding punch through of an underlying layer of etch stop material.

### BACKGROUND OF THE INVENTION

(1) Field of the Invention

The invention relates to the fabrication of integrated circuit devices, and more particularly, to a method of designing a seal ring.

(2) Description of the Prior Art

The creation of semiconductor devices comprises numerous complex and mutually cooperative steps of semiconductor processing during which a large variety of materials and techniques are used. Processing of semiconductor devices is performed in a serial processing stream, which implies that each of the steps of the sequential processing must be essentially error free so as to avoid accumulative errors and the severe negative yield impact that would result therefrom.

This latter requirement implies that semiconductor materials are created where they are required to be created, strictly controlling the occurrence of such materials in any other than the required design configuration. For instance, the accumulation of undesired matter in a location may result in unwanted or catastrophic interconnects or shorts or may create unacceptable parasitic components that have a serious negative effect on the performance and reliability of the created devices.

Since device feature size is continuously being decreased, the control of alien matter must be accordingly increased. This requires that all possible measures must be taken to prevent any negative impact of unwanted environmental particles that are typically present in a semiconductor manufacturing facility.

As a source of particle contamination can be identified the work environment, which comprises particles that originate from a source other than the wafer that is being processed. These particles are typically controlled by extensive steps of clean room creation and maintenance and depend in this context on filtering and a strict control of the working environment, mostly achieved by filtering the components of this working environment.

As another source of particle contamination can be identified the wafer that is being processed since, during processing the wafer is either directly affected by for instance moving the wafer to a different location or is affected by a processing step to which the wafer is subjected at any given time.

This latter source of particle contamination takes on a more serious form if it is considered that wafer processing is becoming more complex, with increasingly more steps of processing sequentially being performed on a wafer before the processing cycle is completed.

This aspect of contamination is further aggravated by the increasingly complex and diverse nature of the materials that are applied to a wafer such as interconnect metals and dielectrics that are applied over a wide range of temperatures.

For this and other reasons, it has become accepted practice to provide a seal ring whereby as a good example of such an application can be cited U.S. Pat. No. 5,723,385 (Shen et al.), which provides a wafer edge seal ring for reduced particle and contaminant generation during wafer processing. This latter application provides for depositing layers at the perimeter of a wafer and gradually spacing the overlying layers at an increased distance from the edge of the wafer.

U.S. Pat. No. 5,891,808 (Chang et al.) teaches a seal ring process and an etch stop.

U.S. Pat. No. 5,723,385 (Shen et al.) shows a seal ring process.

U.S. Pat. No. 6,362,524 B1 (Blish et al.) reveals an edge seal ring for a copper damascene process.

U.S. Pat. No. 6,300,223 B1 (Change et al.) shows a seal ring process.

### SUMMARY OF THE INVENTION

A principle objective of the invention is to create a seal ring around the perimeter of a substrate such that problems of etch stop layer damage is prevented while simultaneously creating dissimilar features such as seal ring vias having dissimilar Critical Dimensions of the seal ring.

In accordance with the objective of the invention a new method is provided for the creation of a seal ring having dissimilar elements. The Critical Dimensions of the seal ring are selected with respect to the CD of other device features, such as seal ring vias, such that the difference in etch sensitivity between the created seal ring and the other device features such as via holes is removed. All etching of the simultaneously etched features is completed at the same time, avoiding punch through of an underlying layer of etch stop material.

### BRIEF DESCRIPTION OF THE DRAWINGS

FIGS. 1a through 1c show cross sections of conventional hole etching.

FIG. 2 shows a cross section of the seal ring of the invention and a therewith associated via opening.

FIG. 3 shows a graph of the relationship between Critical Dimension of an etched surface and the etch rate thereof.

FIG. 4 shows a top view of a semiconductor die, the seal ring and vias created.

### DESCRIPTION OF THE PREFERRED EMBODIMENTS

Prior Art has addressed concerns of punch through of an etch stop layer by selecting the Critical Diameter (CD) of a seal via as being smaller than the CD of a seal ring. This requires selecting the surface area that is being etched such that the etch of the seal ring and the seal via holes completes at about the same time. The invention does not follow this approach. The invention is not based on selecting the surface area of the areas that are concurrently being etched but selects the width of the seal ring and the diameter of the seal vias as the controlling parameters that enable the concurrent completion of the seal ring and the seal vias.

The invention addresses the creation of a seal ring, whereby the seal ring comprises a trench and therewith associated seal ring vias. These two features of trench and vias are simultaneously etched, a process that may result in damage to the applied etch stop layer in view of and caused by the different Critical Dimensions of these two elements. The invention addresses this concern of etch layer damage or punch through and provides a method whereby this damage is avoided.

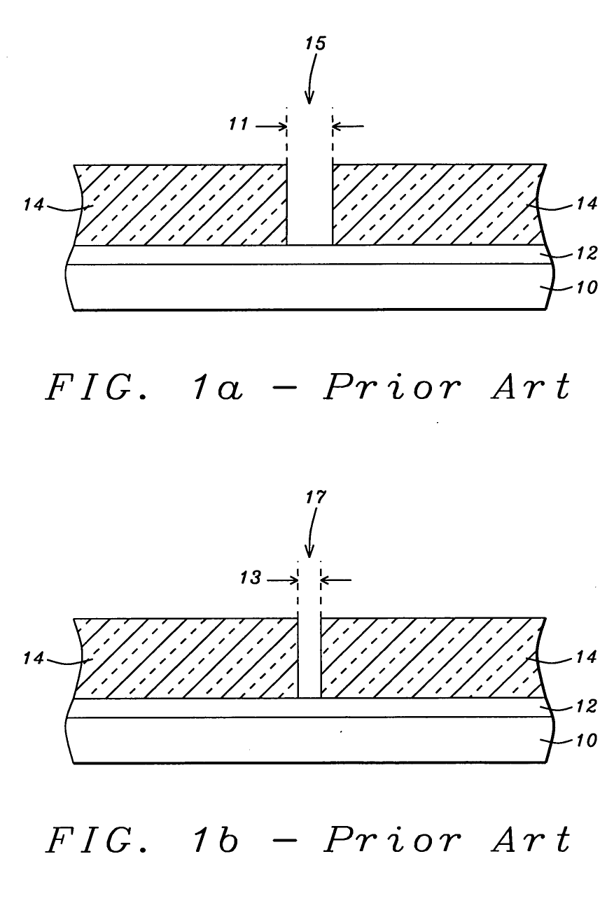

Referring specifically to the cross section of FIGS. 1a and 1b, there is shown the effect on an underlying layer of etch stop material of diameter variation (Critical Diameter or CD variation) when creating an opening through a layer of semiconductor material.

Highlighted in the cross sections of FIGS. 1a and 1b are:
10, a semiconductor surface, typically the surface of a substrate
12, a layer of etch stop material that serves to stop the etch of an opening through an overlying layer of semiconductor material
14, a layer of dielectric through which an opening is to be etched
11, the diameter of a first opening 15 etched through layer 14
13, the diameter of a second opening 17 etched through layer 14.

In comparing diameter 11 with diameter 13, it can be observed and is intended that the value of 11 is larger than the value of 13, meaning that the 15 opening is wider than opening 17.

If both openings 15 and 17 are created using identical methods and conditions of surface etch, opening 15 will be created at a faster rate than opening 17. If therefore the etch for both openings 15 and 17 is performed such that the etch time is also identical, then the etch of opening 15 will affect the surface of etch stop layer 12 before the etch of opening 17 is completed. The result of this is shown in the cross section of FIG. 1c, where the layer 12, where this layer is exposed over the bottom of opening 15, is affected, a phenomenon that is typically referred to as hole punch through.

The cross sections of FIGS. 1b and 1c are to be compared as being the results of equal etch conditions applied to the surface of layer 14 for the etch of two openings of unequal diameter and extending over the same period of time. At the time that the opening of smallest diameter, opening 17, FIG. 1b, is completed through the layer 14 of dielectric, the etch through layer 14 of the opening 15 with larger diameter will have caused punchthrough 19 at the bottom of opening 15.

If, as is shown in the cross section of FIG. 1c, a layer 16 of metal such as copper has been created underlying the created opening 15, the surface of layer 16 will additionally be affected by the etch of opening 15. This exposure of the surface of layer 16 causes arcing and the introduction of copper sputtered polymers into the processing environment, which in turn makes the process of surface clean considerably more difficult.

It is clear that, for a processing environment in which features of different cross sections are simultaneously created as part of one processing cycle, measures are required to prevent etch stop layer punch through. The invention provides such a method.

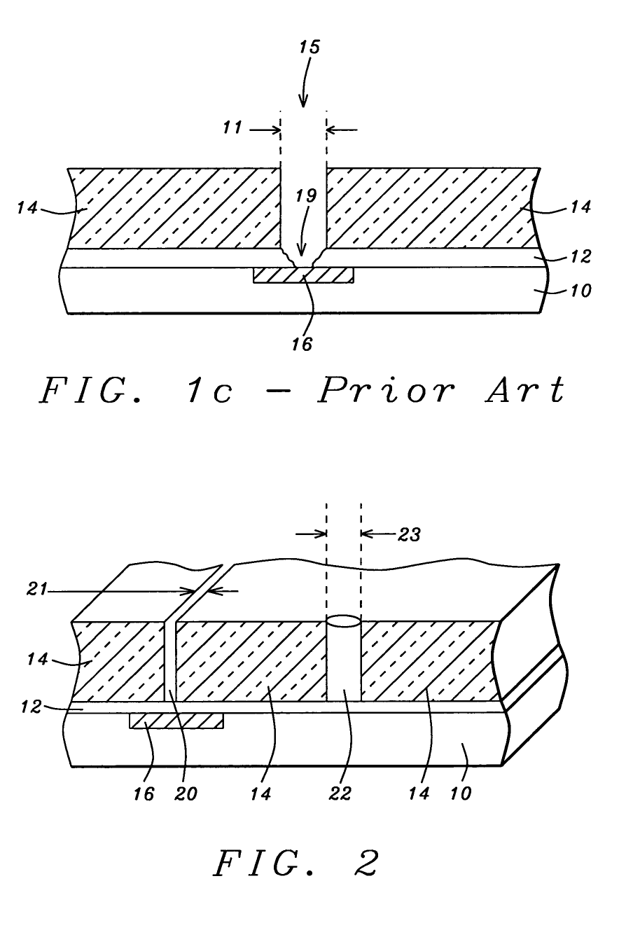

The previously highlighted seal ring that is conventionally provided for protective purposes is created in a processing sequence during which additionally via openings are created, as highlighted in the cross section of FIG. 2.

A number of the highlighted elements of FIG. 2 have previously been highlighted and discussed. Further shown in the three dimensional cross section of FIG. 2 are seal ring trench 20 and a via opening 22, the seal ring having a lateral cross section of width 21 and the via opening 22 having a diameter 23.

It is clear and in line with the previously highlighted cross sections of FIGS. 1a through 1c that it is to be expected that the etch rate for the seal ring 20 and the via opening 22 can not be assumed to be identical. If therefore for instance the seal ring 20 is etched at a higher rate than the via 22, it is to be expected that the surface of layer 12 will be affected where this layer underlies the seal ring 20, with similar undesirable results.

Typically, the seal ring 20 is expected to have a higher etch rate that the via opening 22, resulting in the layer 12 being exposed in the surface of layer 12 underlying the seal ring prior to completion of the etch for opening 22. The etch stop layer 12 will therefore typically be punched through over the bottom surface of seal ring 20. The surface of underlying copper layer 16, FIG. 2, will then be affected, resulting in arcing and the creation of polymer by the arcing and by randomly distributed copper.

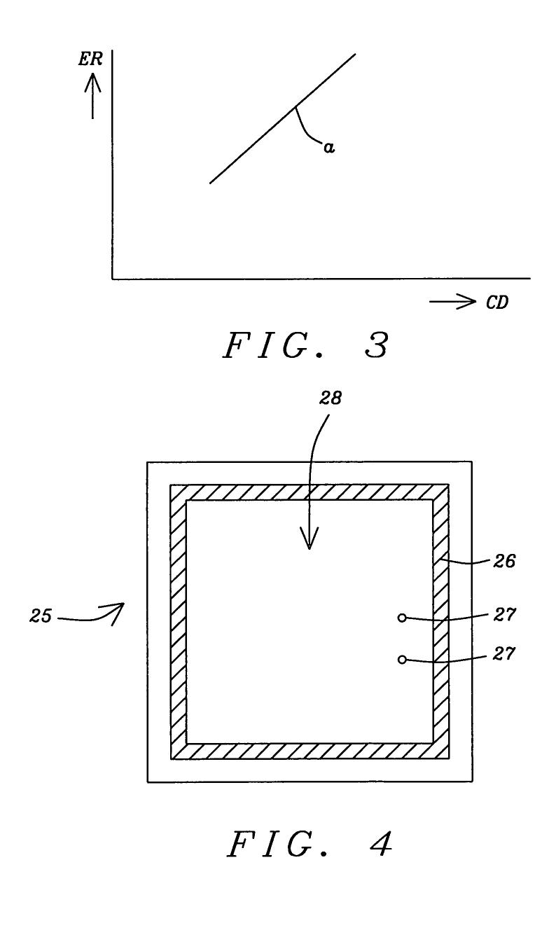

The occurrence of etch rate dependency on the diameter of the etched surface is highlighted in FIG. 3, where the Critical Diameter of the etched surface is plotted along the horizontal or X-axis and the Etch Rate (ER) is plotted along the vertical or Y-axis. The nearly linear relationship between these two parameters is apparent from curve “a” of FIG. 3, whereby an increase in CD results in an increase of the ER. This relationship is rather intuitive since a layer CD means a larger exposed surface so that more of the etch solution has access to the surface that is being etched, increasing the etch rate.

The invention addresses this problem by minimizing the etch rate of the smaller width surface, that is the seal ring 20, FIG. 2, in comparison with the larger diameter surface, that is the via opening 22, FIG. 2. Formally, by providing for:
CD(Seal Ring)<CD(Hole).

As typical and desired examples of the dimensions that are required to achieve the desired effect of simultaneous completion of the seal ring etch and the via hole etch can be cited a CD(hole) of parameter 23, FIG. 2, of about 0.20 μm and a CD(Seal Ring) of parameter 21, FIG. 2, of about 0.15 μm.

By therefore selecting the width 21 of the seal ring 20, shown in the cross section of FIG. 2, and the diameter 23 of the seal vias 22, also shown in the cross section of FIG. 2, such that CD(Seal Ring)<CD(Hole), the seal ring 20 and the seal vias 22 can be simultaneously etched such that the etch of both seal ring 20 and seal vias 22 reaches the surface of the etch stop layer 12 at about the same time, thus preventing etch stop punch through.

FIG. 4 further provides a top view of a semiconductor die 25 around the perimeter of which has been provided a seal ring 26. The seal ring 26 surrounds the active surface area 28 of the die, concurrent with the etching of seal ring 26 is etched over the surface of die 25 a pattern of via openings of which vias 27 have been highlighted as being representative examples. From the top view shown in FIG. 4 it clear that the surface of seal ring 26 that is exposed during etch of this seal ring has a significantly larger surface area than the via openings 27. From this it can be concluded that the etch rate for the etch of seal ring 26 must be reduced so that the etch of both seal ring 26 and vias 27 is completed at about the same time.

The exposed surface of seal ring 26 must therefore be reduced relative to the exposed surface of vias 27, leading to the above formalized relationship between these two entities.

The invention can be further extended by including the creation of alignment marks, whereby the alignment marks take the position of the previously discussed vias as being features having an exposed surface that is smaller than the surface area of a seal ring and that therefore tends to be etched at a slower rate than the seal ring. The surface area of the seal ring must therefore also be adjusted and be reduced with respect to the surface area of the alignment mark.

The invention, which provides a method for the creation of a seal ring over a semiconductor device, can be summarized as follows:
providing a substrate, said substrate having been provided with semiconductor devices, and
concurrently patterning a seal ring having a first Critical Dimension and at least one via opening having a second Critical Dimension and at least one Alignment Mark having a third Critical Dimension in a layer of dielectric deposited over the substrate, the first Critical Dimension and the second Critical Dimension the third Critical Dimension being mutually dependent
the first Critical Dimension being smaller than the second Critical Dimension and the third Critical Dimension
the first Critical Dimension being about 0.15 μm
the second Critical Dimension being about 0.20 μm
the third Critical Dimension being about 0.20 μm.

Although the invention has been described and illustrated with reference to specific illustrative embodiments thereof, it is not intended that the invention be limited to those illustrative embodiments. Those skilled in the art will recognize that variations and modifications can be made without departing from the spirit of the invention. It is therefore intended to include within the invention all such variations and modifications which fall within the scope of the appended claims and equivalents thereof.

1. A method for the creation of a seal ring over a semiconductor device, comprising:
providing a substrate, said substrate having been provided with semiconductor devices;
patterning in a layer of dielectric deposited over the substrate first device features having a width dimension concurrent with patterning second device features having a diameter dimension, the width dimension being smaller than the diameter dimension.

2. The method of claim 1, the first device features comprising a device seal ring.

3. The method of claim 1, the second device features comprising via openings.

4. The method of claim 1, the second device features comprising at least one Alignment Mark.

5. The method of claim 1, the width dimension being about 0.15 μm.

6. The method of claim 1, the diameter dimension being about 0.20 μm.

7. A method for the creation of a seal ring over a semiconductor device, comprising:
providing a substrate, said substrate having been provided with semiconductor devices; and
concurrently patterning a seal ring having a width dimension and via openings having a diameter dimension in a layer of dielectric deposited over the substrate, the width dimension and the diameter dimension being mutually dependent.

8. The method of claim 7, the width dimensions being smaller than the diameter dimensions.

9. The method of claim 7, the width dimension being about 0.15 μm.

10. The method of claim 7, the diameter dimension being about 0.20 μm.

11. A method for the creation of a seal ring over a semiconductor device, comprising:
providing a substrate, said substrate having been provided with semiconductor devices; and
concurrently patterning a seal ring having a width dimension and via openings having a diameter dimension in a layer of dielectric deposited over the substrate, the width dimensions being about 0.15 μm, the diameter dimension being about 0.20 μm.

12. A method for the creation of a seal ring over a semiconductor device, comprising:
providing a substrate, said substrate having been provided with semiconductor devices; and
concurrently patterning a seal ring having a first Critical Dimension and at least one Alignment Mark having a second Critical Dimension in a layer of dielectric deposited over the substrate, the first Critical Dimension and the second Critical Dimension being mutually dependent.

13. The method of claim 12, the first Critical Dimension being smaller than the second Critical Dimension.

14. The method of claim 12, the first Critical Dimension being about 0.15 μm.

15. The method of claim 12, the second Critical Dimension being about 0.20 μm.

16. A method for the creation of a seal ring over a semiconductor device, comprising:
providing a substrate, said substrate having been provided with semiconductor devices; and
concurrently patterning a seal ring having a first Critical Dimension and at least one alignment Mark having a second Critical Dimension in a layer of dielectric deposited over the substrate, the first Critical Dimension being smaller than the second Critical Dimension.

17. The method of claim 16, the first Critical Dimension being about 0.15 μm.

18. The method of claim 16, the second Critical Dimension being about 0.20 μm.

19. A method for the creation of a seal ring over a semiconductor device, comprising:
providing a substrate, said substrate having been provided with semiconductor devices; and
concurrently patterning a seal ring having a first Critical Dimension and at least one via opening having a second Critical Dimension and at least one Alignment Mark having a third Critical Dimension in a layer of dielectric deposited over the substrate, the first Critical Dimension and the second Critical Dimension the third Critical Dimension being mutually dependent.

20. The method of claim 19, the first Critical Dimension being smaller than the second Critical Dimension and the third Critical Dimension.

21. The method of claim 19, the first Critical Dimension being about 0.15 μm.

22. The method of claim 19, the second Critical Dimension being about 0.20 μm.

23. The method of claim 19, the third Critical Dimension being about 0.20 μm.

24. A method for the creation of a seal ring over a semiconductor device, comprising:
providing a substrate, said substrate having been provided with semiconductor devices; and
concurrently patterning a seal ring having a first Critical Dimension and at least one via opening having a second Critical Dimension and at least one Alignment Mark having a third Critical Dimension in a layer of dielectric deposited over the substrate, the first Critical Dimension being smaller than the second Critical Dimension and the third Critical Dimension.

25. The method of claim 24, the first Critical Dimension being about 0.15 μm.

26. The method of claim 24, the second Critical Dimension being about 0.20 μm.

27. The structure of a seal ring over a semiconductor device, comprising:
a substrate, said substrate having been provided with semiconductor devices;
in a layer of dielectric deposited over the substrate, a pattern of first device features having a width dimension and a pattern of second device features having a diameter dimension, the width dimension being smaller than the diameter dimension.

28. The structure of claim 27, the first device features comprising a device seal ring.

29. The structure of claim 27, the second device features comprising via openings.

30. The structure of claim 27, the second device features comprising at least one Alignment Mark.

31. The structure of claim 27, the width dimension being about 0.15 μm.

32. The structure of claim 27, the diameter dimension being about 0.20 μm.

33. A structure of a seal ring over a semiconductor device, comprising:
a substrate, said substrate having been provided with semiconductor devices; and
a seal ring having a width dimension and via openings having a diameter dimension having been patterned in a layer of dielectric deposited over the substrate, the width dimension and the diameter dimension being mutually dependent.

34. A structure of claim 33, the width dimensions being smaller than the diameter dimensions.

35. A structure of claim 33, the width dimension being about 0.15 μm.

36. A structure of claim 33, the diameter dimension being about 0.20 μm.

37. A structure of a seal ring over a semiconductor device, comprising:
a substrate, said substrate having been provided with semiconductor devices; and
a seal ring having a width dimension and via openings having a diameter dimension having been patterned in a layer of dielectric deposited over the substrate, the width dimensions being about 0.15 μm, the diameter dimension being about 0.20 μm.

38. A structure of a seal ring over a semiconductor device, comprising:
a substrate, said substrate having been provided with semiconductor devices; and
a seal ring having a first Critical Dimension and at least one Alignment Mark having a second Critical Dimension having been patterned in a layer of dielectric deposited over the substrate, the first Critical Dimension and the second Critical Dimension being mutually dependent.

39. The structure of claim 38, the first Critical Dimension being smaller than the second Critical Dimension.

40. The structure of claim 38, the first Critical Dimension being about 0.15 μm.

41. The structure of claim 38, the second Critical Dimension being about 0.20 μm.

42. A structure of a seal ring over a semiconductor device, comprising:
providing a substrate, said substrate having been provided with semiconductor devices; and
concurrently patterning a seal ring having a first Critical Dimension and at least one alignment Mark having a second Critical Dimension in a layer of dielectric deposited over the substrate, the first Critical Dimension being smaller than the second Critical Dimension.

43. The structure of claim 42, the first Critical Dimension being about 0.15 μm.

44. The structure of claim 42, the second Critical Dimension being about 0.20 μm.

45. A structure of a seal ring over a semiconductor device, comprising:
a substrate, said substrate having been provided with semiconductor devices; and
a seal ring having a first Critical Dimension and at least one via opening having a second Critical Dimension and at least one Alignment Mark having a third Critical Dimension having been patterned in a layer of dielectric deposited over the substrate, the first Critical Dimension and the second Critical Dimension the third Critical Dimension being mutually dependent.

46. The structure of claim 45, the first Critical Dimension being smaller than the second Critical Dimension and the third Critical Dimension.

47. The structure of claim 45, the first Critical Dimension being about 0.15 μm.

48. The structure of claim 45, the second Critical Dimension being about 0.20 μm.

49. The structure of claim 45, the third Critical Dimension being about 0.20 μm.

50. A structure of a seal ring over a semiconductor device, comprising:
a substrate, said substrate having been provided with semiconductor devices; and
a seal ring having a first Critical Dimension and at least one via opening having a second Critical Dimension and at least one Alignment Mark having a third Critical Dimension having been patterned in a layer of dielectric deposited over the substrate, the first Critical Dimension being smaller than the second Critical Dimension and the third Critical Dimension.

51. The structure of claim 50, the first Critical Dimension being about 0.15 μm.

52. The structure of claim 50, the second Critical Dimension being about 0.20 μm.
